(19) United States
(12) Patent Application Publication
(10) Pub. No.: US 2009/0243032 A1
(43) Pub. Date: Oct. 1, 2009

(54) ELECTRICAL FUSE STRUCTURE

(76) Inventor: Shi-Bai Chen, Taichung City (TW)

Correspondence Address: NORTH AMERICA INTELLECTUAL PROPERTY CORPORATION, P.O. BOX 506, MERRIFIELD, VA, 22116, US

(21) Appl. No.: 12/056,289

(22) Filed: Mar. 27, 2008

(51) Int. Cl. H01L 23/525

(52) U.S. Cl. 257/529; 257/506; 257/E23.149; 257/E23.151

(57) ABSTRACT

An e-fuse structure includes a cathode block; a plurality of cathode contact plugs on the cathode block; an anode block; a plurality of anode contact plugs on the cathode block; and a fuse link connecting the cathode block with the anode block, wherein a front row of the cathode contact plugs is disposed in close proximity to the fuse link thereby inducing a high thermal gradient at an interface between the cathode block and the fuse link.

### BACKGROUND OF THE INVENTION

1. Field of the Invention

The present invention relates generally to a microelectronic device and, more particularly, to an electrical fuse (e-fuse) structure utilizing electro-migration mode. The invention e-fuse structure can be employed in semiconductor integrated circuits using 90 nm or below technology and has improved yield and reliability.

2. Description of the Prior Art

As feature sizes of VLSI devices continue to shrink, it becomes increasingly difficult to maintain good yields. This makes it more important than ever to implement logic circuits with built-in redundancy that allows for repair by switching over to a backup element if a circuit element fails. This circuit switching for repair purposes is generally accomplished by a fuse, and a variety of methods has been developed, including laser fusing that uses an external laser to burn through the wire and electrical fusing (e-fuse) that uses electricity to blow the fuse material.

One problem with the laser fuses is that their dimensions have not been shrinking even as microchip wiring and components have gotten smaller. That is because the fuses' dimensions are tied to the wavelength of the laser and the resolution limits of the optics used to cut them, which are several times as large as the features that make up the transistors on new chips.

The e-fuse solution in particular has been extensively applied to CMOS processes because it involves few positioning restraints and doesn't require any special device to implement the blowing scheme. Generally, an e-fuse is composed of a tiny strip of polysilicon covered with a thin layer of cobalt silicide or nickel silicide, the same materials that make up a transistor gate. The fuse is opened through a process called electromigration, in which current pushes the atoms in small wires out of place.

FIG. 1 is a schematic diagram depicting the layout of a conventional e-fuse. As shown in FIG. 1, the e-fuse 1 has three blocks including a cathode block 12, an anode block 14 and a fuse link 16 that connects the cathode block 12 with the anode block 14. The cathode block 12, the anode block 14 and the fuse link 16 are defined at the same time and are composed of a polysilicon layer and a silicide layer. A plurality of contact plugs 22 are provided directly on the cathode block 12. A plurality of contact plugs 24 are provided directly on the anode block 14.

Typically, the cathode block 12 has a larger surface area than that of the anode block 14. Besides, the distance L₁ between the first row of contact plugs 22 and the fuse link 16 is much greater than the distance L₂ between the first row of contact plugs 24 and the fuse link 16 for the sake of reservoir effect. According to the prior art, no contact plug is disposed in the transition region 26 on the cathode block 12 between the first row of contact plugs 22 and the fuse link 16. Ordinarily, the distance L₁ is about 5˜10 times the dimension of a contact plug 22. It is believed that the transition region 26 can provide sufficient silicide source during the electro-migration process of the silicide layer.

The polysilicon in the fuse is a poor conductor at room temperature. Cobalt silicide or nickel silicide, on the other hand, is a good conductor, so most of the electron current (in the direction indicated by the arrow 28) applied to the polysilicon-silicide strip goes through the silicide. At sufficiently high current, electromigration occurs, and atoms in the silicide begin to drift along with the electrons in the current, from the cathode block 12 to the anode block 14, eventually making a gap in the material.

At the same time, the high density of current through the fuse causes it to heat up. Once it is hot, electromigration increases in the silicide, and the conductivity of the underlying polysilicon goes up as well, allowing current to pass through it. So electromigration continues even after a break forms in the silicide. After a time the current is removed, the e-fuse 1 cools down, the polysilicon becomes a poor conductor again, and the e-fuse 1 stays permanently open.

However, when the aforesaid prior art e-fuse 1 is applied in the advanced manufacturing process such as line widths of 90 nm or beyond, both of the yield and reliability decrease. Therefore, there is a need in this industry to provide an improved electrical fuse structure used in semiconductor integrated circuits.

### SUMMARY OF THE INVENTION

It is one object of the present invention to provide a polycide e-fuse structure employed in semiconductor integrated circuits using 90 nm or below technology with improved yield and reliability.

A first preferred embodiment is an e-fuse structure comprising a cathode block; a plurality of cathode contact plugs on the cathode block; an anode block; a plurality of anode contact plugs on the anode block; and a fuse link connecting the cathode block with the anode block, wherein a front row of the cathode contact plugs is disposed in close proximity to the fuse link thereby inducing a high thermal gradient at an interface between the cathode block and the fuse link.

In another aspect, an electrical fuse structure is provided which includes a cathode block; a plurality of cathode contact plugs on the cathode block; an anode block; a plurality of anode contact plugs on the anode block; a fuse link connecting the cathode block with the anode block; and a heat sink structure disposed on the cathode block between the plurality of cathode contact plugs and the fuse link.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a schematic diagram depicting the layout of a conventional e-fuse;

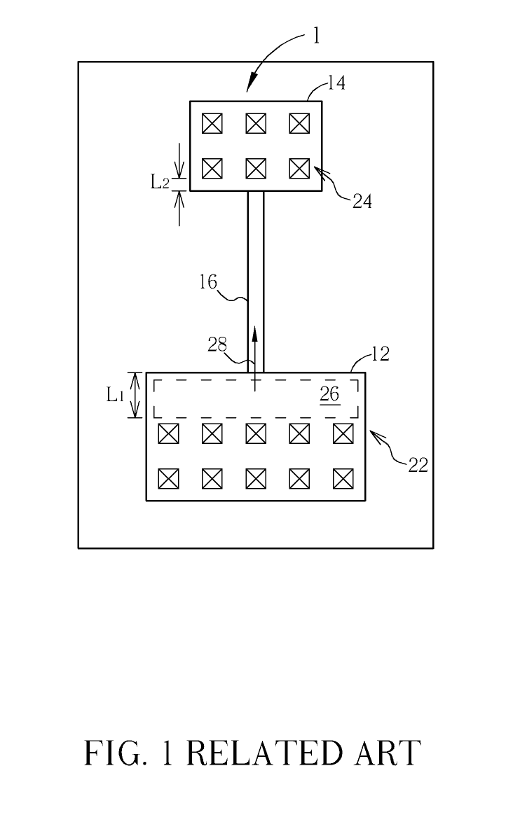

FIG. 2 is a schematic, perspective diagram depicting an e-fuse structure in accordance with the first preferred embodiment of this invention;

FIG. 3 demonstrates the experimental results and yields of the first preferred embodiment of this invention;

FIG. 4 is a schematic, perspective diagram depicting an e-fuse structure in accordance with the second preferred embodiment of this invention; and

FIG. 5 demonstrates the experimental results and yields of the second preferred embodiment of this invention.

### DETAILED DESCRIPTION

The present invention pertains to a polysilicon-silicide e-fuse (hereinafter polycide e-fuse) that takes advantage of electro-migration (EM) effects with opening of the fuse. The inventive polycide e-fuse structure can meet the requirements below the 90 nm technology level and can improve yield and reliability when programming or blowing the e-fuse. The polycide e-fuse described herein is fabricated of silicide disposed on a polysilicon support structure.

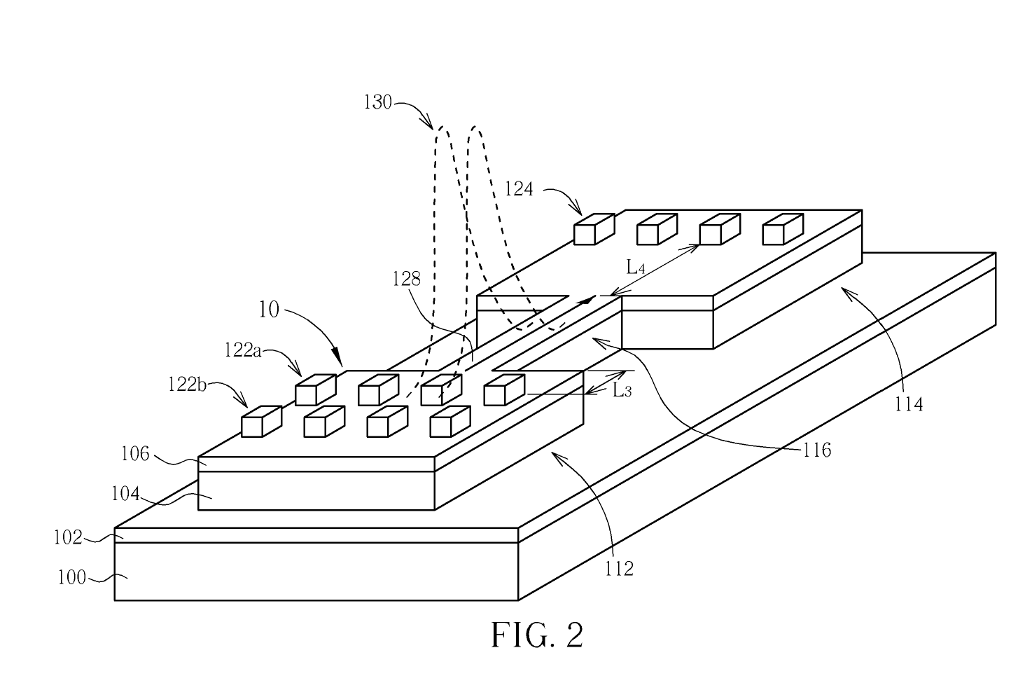

Please refer to FIG. 2. FIG. 2 is a schematic, perspective diagram depicting an exemplary polycide e-fuse structure in accordance with the first preferred embodiment of this invention. As shown in FIG. 2, the polycide e-fuse structure 10 is formed over an insulating layer 102. The insulating layer 102 includes an oxide layer such as silicon oxide dielectric layer or shallow trench isolation (STI) oxide fill layer, which is formed on a semiconductor substrate 100 such as a silicon substrate or a silicon-on-insulator (SOI) substrate. However, in some cases, the polycide e-fuse structure 10 is formed on an oxide-defined (OD) region or active area depending on the design of the integrated circuits.

According to the first preferred embodiment, the polycide e-fuse structure 10 is a dual-layer composite structure composed of a polysilicon layer 104 and a silicide layer 106. The silicide layer 106 is laminated on the polysilicon layer 104. The silicide layer 106 includes but not limited to nickel silicide, cobalt silicide and titanium silicide. It is understood that at least one inter-layer dielectric (ILD) layer such as silicon oxide or silicon nitride is deposited over the semiconductor substrate 100 to cover the polycide e-fuse structure 10, which is not shown in the figures for the sake of simplicity.

The polycide e-fuse structure 10 comprises three blocks including a cathode block 112, an anode block 114 and a fuse link 116 that connects the cathode block 112 with the anode block 114. According to the preferred embodiment, the polycide e-fuse structure 10 is dumbbell shaped. Preferably, the cathode block 112 has a surface area that is substantially the same as that of the anode block 114. A plurality of contact plugs 122 are provided directly on the cathode block 112. A plurality of contact plugs 124 are provided directly on the anode block 114.

When a potential is applied across the polycide e-fuse structure 10, electron current flows from the cathode block 112 to the anode block 114 through the fuse link 116 (as indicated by the arrow 128). The aforesaid potential is provided by a first metal line (not shown) connecting and overlying the plurality of cathode contact plugs 122 and a second metal line (not shown) connecting and overlying the plurality of anode contact plugs 124. The high density of current through the polycide e-fuse structure 10 causes it to heat up and induce thermal gradient at the interface between the cathode block 112 and the fuse link 116.

It is one germane feature of the present invention that the cathode contact plugs 122 are disposed as close as possible to the fuse link 116 such that an increased thermal gradient 130 higher than that of prior art is induced. According to the preferred embodiment of this invention, the distance L₃ between the front-row cathode contact plugs 122a and the fuse link 116 is less than a dimension of each of the cathode contact plugs 122a and 122b.

According to the experimental results, the increased thermal gradient 130 induced at the interface between the cathode block 112 and the fuse link 116 shortens the span of time that is required to completely migrate the silicide layer 106 of the fuse link 116 to form an open e-fuse. Also, the increased thermal gradient improves the yield.

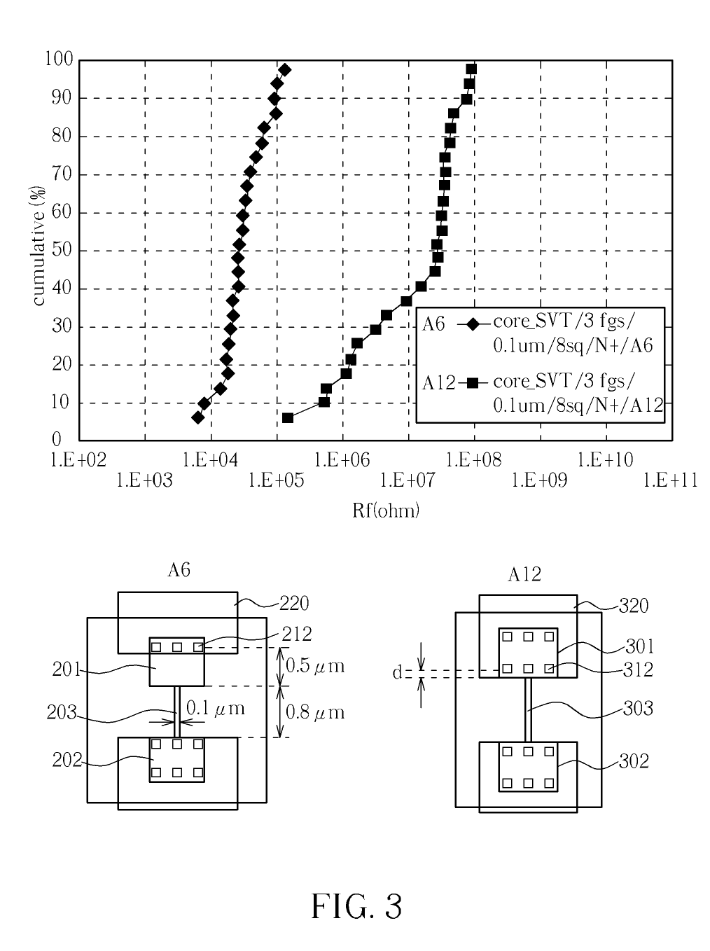

The experimental results and yields are depicted in FIG. 3. The two cumulative (%) vs. Rf (ohm) curves corresponds to the two testing e-fuse structures A6 and A12, respectively. The exemplary testing e-fuse structures A6 and A12 are fabricated using a 90 nm technology and both have a ground rule of 0.1 μm. For example, the testing e-fuse structure A6 has a cathode pad 201, an anode pad 202 and 0.1 μm×0.8 μm fuse link 203 that connects the cathode pad 201 to the anode pad 202. One row of 0.1 μm×0.1 μm contact plugs 212 are disposed on the cathode pad 201.

A metal line 220 is interconnected with the row of contact plugs 212. The distance between the row of contact plugs 212 and the fuse link 203 of the exemplary testing e-fuse structure A6 is about 0.5 μm (approximately 5 times the dimension of the contact plug 212). This vacated, no-contact plug area between the contact plugs 212 and the fuse link 203 of the exemplary testing e-fuse structure A6 is also known as a reservoir region that is deliberately preserved for silicide electro-migration.

The testing e-fuse structure A12 has a cathode pad 301 (having the same size as that of cathode pad 201), an anode pad 302 (having the same size as that of anode pad 202) and 0.1 μm×0.8 μm fuse link 303 that connects the cathode pad 301 to the anode pad 302. The difference between the testing e-fuse structures A6 and A 12 includes that there are two rows of contact plugs 312 disposed on the cathode pad 301. The front row (or the first row) of the contact plugs 312 is in very close proximity to the fuse link 303.

Preferably, the distance d between the front row of the contact plugs 312 and the fuse link 303 is less than the dimension of each of the contact plugs 312, e.g., d<0.1 μm. When a potential or pulse such as 1.8V/1 μs is applied across the e-fuse structure, the front row of the contact plugs 312 and the metal line 320 that is also in close proximity to the fuse link 303 can rapidly dissipate the heat and induce a desirable abrupt, high thermal gradient at the interface between the cathode pad 301 and the fuse link 303. Another advantage of the present invention is that since the number of cathode contact plugs disposed on the cathode pad is increased, the resistance of the e-fuse is decreased.

Furthermore, referring briefly back to FIG. 2, a distance L₄ between the anode contact plugs 124 and the fuse link 116 may be more than a dimension of each of the anode contact plugs. The longer distance L₄ between the anode contact plugs 124 and the fuse link 116 help elevate the temperature at the central portion of the fuse link 116, and thus further increase the thermal gradient occurring thereto.

It is the main objective to create a more abrupt and higher thermal gradient at the interface between the cathode pad and the fuse link of the e-fuse, thereby improving the yield when blowing or opening the e-fuse. To serve the purpose of the invention, a second preferred embodiment is proposed.

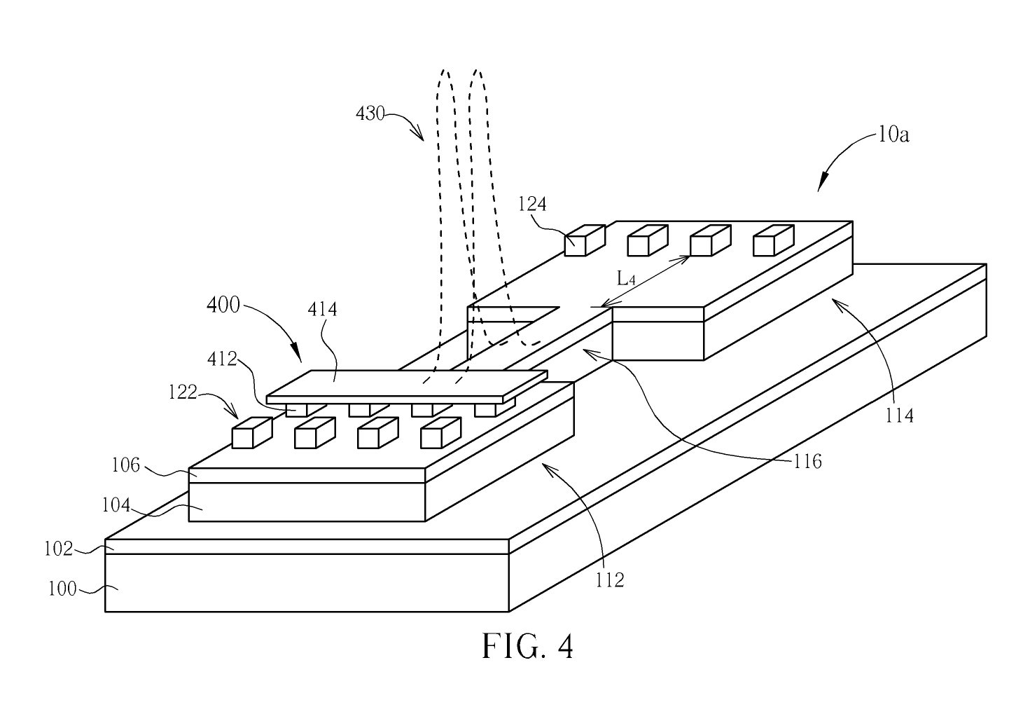

Please refer to FIG. 4. FIG. 4 is a schematic, perspective diagram depicting an exemplary polycide e-fuse structure in accordance with the second preferred embodiment of this invention. As shown in FIG. 4, likewise, the polycide e-fuse structure 10a is formed over an insulating layer 102. The insulating layer 102 includes an oxide layer such as silicon oxide dielectric layer or STI oxide fill layer, which is formed on a semiconductor substrate 100 such as a silicon substrate or an SOI substrate. In some embodiments, the polycide e-fuse structure 10a is formed on an OD region or active area depending on the design of the integrated circuits.

The polycide e-fuse structure 10a is a dual-layer composite structure composed of a polysilicon layer 104 and a silicide layer 106. The silicide layer 106 is laminated on the polysilicon layer 104. The silicide layer 106 includes but not limited to nickel silicide, cobalt silicide and titanium silicide. It is understood that at least one ILD layer such as silicon oxide or silicon nitride is deposited over the semiconductor substrate 100 to cover the polycide e-fuse structure 10a, which is not shown in the figures for the sake of simplicity.

The polycide e-fuse structure 10a comprises three blocks including a cathode block 112, an anode block 114 and a fuse link 116 that connects the cathode block 112 with the anode block 114. According to the second preferred embodiment, the polycide e-fuse structure 10a is dumbbell shaped. Preferably, the cathode block 112 has a surface area that is substantially the same as that of the anode block 114. A plurality of contact plugs 122 are provided directly on the cathode block 112. A plurality of contact plugs 124 are provided directly on the anode block 114.

According to the second preferred embodiment, a heat sink structure 400 is disposed on the cathode block 112 between contact plugs 122 and the fuse link 116. The heat sink structure 400 is composed of at least one row of contact plugs 412 and at least one metal plate 414 stacked on the contact plugs 412. Preferably, the heat sink structure 400 is disposed as close to the fuse link 116 as possible. The metal plate 414 may overlap with the fuse link 116 in a plane view and may have any shape or pattern that is capable of increasing the heat dissipating efficiency. In other embodiments, the heat sink structure may have multiple layers of contact or via plugs and multiple layers of metal lines.

According to the second preferred embodiment, the heat sink structure 400 may be electrically floating. That is, the metal plate 414, which is fabricated and defined concurrently with the first layer metal interconnection (or metal-1), may not connect with any signal line of metal-1. However, in the case that the heat sink structure has multiple layers of contact or via plugs and metal lines, one of the metal layers of the heat sink structure may connect to the interconnection layer such as ground layer of the integrated circuit.

When a potential is applied across the polycide e-fuse structure 10a, electron current flows from the cathode block 112 to the anode block 114 through the fuse link 116. The aforesaid potential is provided by a first metal line (not shown) connecting and overlying the plurality of cathode contact plugs 122 and a second metal line (not shown) connecting and overlying the plurality of anode contact plugs 124. The high density of current through the polycide e-fuse structure 10a causes it to heat up and induce thermal gradient at the interface between the cathode block 112 and the fuse link 116. The heat sink structure 400 can induce a more abrupt and higher thermal gradient 430 at the interface between the cathode block 112 and the fuse link 116.

According to the experimental results, the high thermal gradient 430 induced at the interface between the cathode block 112 and the fuse link 116 shortens the span of time that is required to completely migrate the silicide layer 106 of the fuse link 116 to form a gap in silicide layer 106.

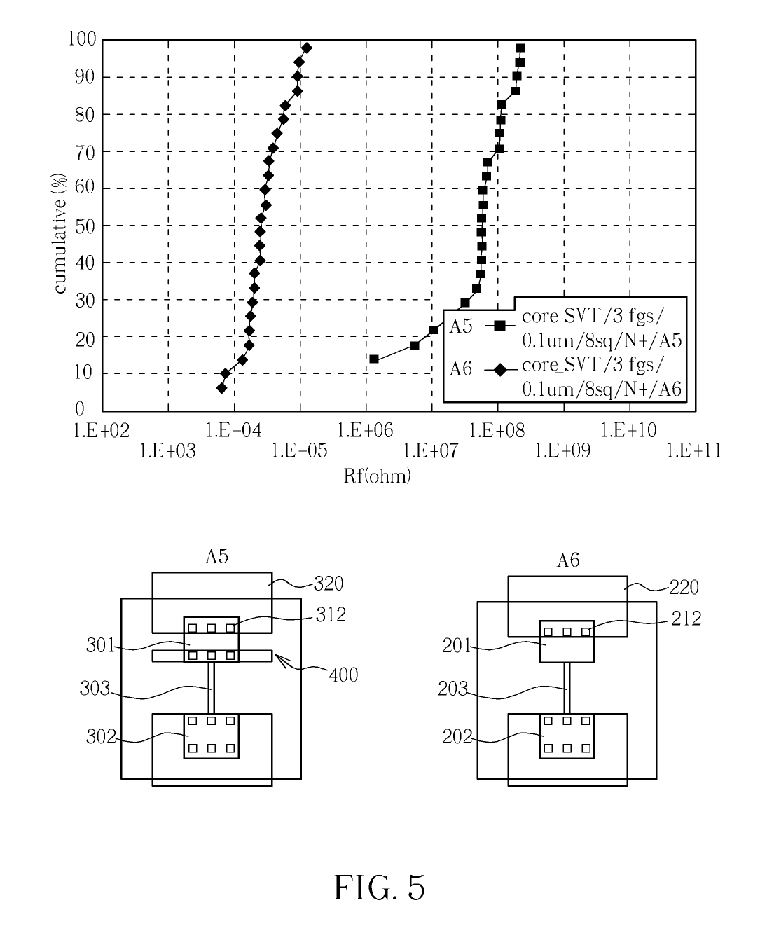

The experimental results and yields are depicted in FIG. 5. The two cumulative (%) vs. Rf (ohm) curves corresponds to the two testing e-fuse structures A6 and A5, respectively. The exemplary testing e-fuse structures A6 and A5 are fabricated using a 90 nm technology and both have a ground rule of 0.1 μm. The testing e-fuse structure A6 has a cathode pad 201, an anode pad 202 and 0.1 μm×0.8 μm fuse link 203 that connects the cathode pad 201 to the anode pad 202. One row of 0.1 μm×0.1 μm contact plugs 212 are disposed on the cathode pad 201.

A metal line 220 is interconnected with the row of contact plugs 212. The distance between the row of contact plugs 212 and the fuse link 203 is about 0.5 μm (5 times the dimension of the contact plug 212). This area is known as a reservoir region that is deliberately preserved for facilitating silicide electro-migration phenomenon.

The testing e-fuse structure A5 has a cathode pad 301 (having the same size as that of cathode pad 201), an anode pad 302 (having the same size as that of anode pad 202) and 0.1 μm×0.8 μm fuse link 303 that connects the cathode pad 301 to the anode pad 302. One row of 0.1 μm×0.1 μm contact plugs 312 are disposed on the cathode pad 301. The difference between the testing e-fuse structures A6 and A 5 is the heat sink structure 400.

When a potential or pulse such as 1.8V/1 μs is applied across the e-fuse structure, the heat sink structure 400 rapidly dissipates the heat and induce a desirable abrupt, high thermal gradient at the interface between the cathode pad 301 and the fuse link 303, thereby improving the yield when blowing or opening the e-fuse.

Those skilled in the art will readily observe that numerous modifications and alterations of the device and method may be made while retaining the teachings of the invention.

What is claimed is:

1. An electrical fuse structure, comprising:
a cathode block;
a plurality of cathode contact plugs on the cathode block;
an anode block;
a plurality of anode contact plugs on the anode block; and
a fuse link connecting the cathode block with the anode block, wherein a front row of the cathode contact plugs is disposed in close proximity to the fuse link thereby inducing a high thermal gradient at an interface between the cathode block and the fuse link.

2. The electrical fuse structure according to claim 1 wherein a distance between the front row of the cathode contact plugs and the fuse link is less than a dimension of each of the cathode contact plugs.

3. The electrical fuse structure according to claim 1 wherein a distance between the anode contact plugs and the fuse link is more than a dimension of each of the anode contact plugs.

4. The electrical fuse structure according to claim 1 wherein the front row of the cathode contact plugs is connected with an overlying metal plate, and wherein the metal plate and the front row of cathode contact plugs constitute a heat sink structure.

5. The electrical fuse structure according to claim 1 wherein the cathode block, the anode block and the fuse link are composed of polycide comprising a layer of polysilicon and a layer of silicide.

6. The electrical fuse structure according to claim 5 wherein the silicide comprises nickel silicide, cobalt silicide and titanium silicide.

7. The electrical fuse structure according to claim 1 wherein the cathode block, the anode block and the fuse link are arranged in a dumbbell shape.

8. The electrical fuse structure according to claim 1 wherein the cathode block has a surface area that is substantially the same as that of the anode block.

9. The electrical fuse structure according to claim 1 wherein the cathode block, the anode block and the fuse link are formed on an insulating layer.

10. The electrical fuse structure according to claim 9 wherein the insulating layer includes shallow trench isolation (STI) trench fill layer.

11. The electrical fuse structure according to claim 1 wherein the cathode block, the anode block and the fuse link are formed on an oxide-defined region or active area.

12. An electrical fuse structure, comprising:
a cathode block;
a plurality of cathode contact plugs on the cathode block;
an anode block;
a plurality of anode contact plugs on the anode block;
a fuse link connecting the cathode block with the anode block; and
a heat sink structure disposed on the cathode block between the plurality of cathode contact plugs and the fuse link.

13. The electrical fuse structure according to claim 12 wherein the heat sink structure is composed of at least one row of contact plugs and at least one metal plate stacked on the contact plugs.

14. The electrical fuse structure according to claim 12 wherein the heat sink structure is electrically floating.

15. The electrical fuse structure according to claim 12 wherein the cathode block, the anode block and the fuse link are composed of polycide comprising a layer of polysilicon and a layer of silicide.

16. The electrical fuse structure according to claim 15 wherein the silicide comprises nickel silicide, cobalt silicide and titanium silicide.

17. The electrical fuse structure according to claim 12 wherein the cathode block, the anode block and the fuse link are arranged in a dumbbell shape.

18. The electrical fuse structure according to claim 12 wherein the cathode block has a surface area that is substantially the same as that of the anode block.

19. The electrical fuse structure according to claim 12 wherein the cathode block, the anode block and the fuse link are formed on an insulating layer.

20. The electrical fuse structure according to claim 19 wherein the insulating layer includes shallow trench isolation (STI) trench fill layer.

21. The electrical fuse structure according to claim 12 wherein the cathode block, the anode block and the fuse link are formed on an oxide-defined region or active area.
